(19) United States
(12) Patent Application Publication
(10) Pub. No.: US 2024/0427234 A1
(43) Pub. Date: Dec. 26, 2024

(54) IMPRINT METHOD AND METHOD FOR MANUFACTURING SEMICONDUCTOR DEVICE

(71) Applicant: Kioxia Corporation, Tokyo (JP)

(72) Inventors: Kazuya FUKUHARA, Yokkaichi Mie (JP); Masayuki HATANO, Yokohama Kanagawa (JP); Tetsuro NAKASUGI, Yokohama Kanagawa (JP)

(21) Appl. No.: 18/745,514

(22) Filed: Jun. 17, 2024

(30) Foreign Application Priority Data
Jun. 20, 2023 (JP) 2023-100948

(51) Int. Cl. G03F 7/00; G03F 7/16; H01L 21/027; H01L 21/311

(52) U.S. Cl. CPC G03F 7/0002; G03F 7/162; H01L 21/0274; H01L 21/31144; H01L 21/31105

(57) ABSTRACT

An imprint method includes: forming a liquid film of a first photocurable resin to have a substantially flat upper surface on a central region of a substrate; depositing droplets of a second photocurable resin on an outer peripheral region of the substrate; pressing a template against the first photocurable resin and the second photocurable resin; irradiating the first photocurable resin and the second photocurable resin with light to cure the first photocurable resin and the second photocurable resin; and releasing the template from the first photocurable resin and the second photocurable resin to expose a pattern on the substrate, that is formed by the cured first photocurable resin and the cured second photocurable resin.

### CROSS-REFERENCE TO RELATED APPLICATION(S)

This application is based upon and claims the benefit of priority from Japanese Patent Application No. 2023-100948, filed Jun. 20, 2023, the entire contents of which are incorporated herein by reference.

### FIELD

Embodiments described herein relate generally to an imprint method and a method for manufacturing a semiconductor device.

### BACKGROUND

Imprint processing may be used in a manufacturing step of a semiconductor device. During imprint processing, a template having an uneven portion is pressed against a resist layer formed in a predetermined region of a substrate for each shot. When a concave portion of the template is filled with a resist, a projection portion is formed thereby in the resist layer.

When a formation amount of the resist layer in the predetermined region is small, the concave portion of the template may not be sufficiently filled with the resist. In addition, the substrate and the template may come into contact with each other, and an alignment operation may be inhibited by a shearing force. As a result, a defect may occur.

On the other hand, when the resist layer is formed to protrude from the predetermined region, the template may be contaminated by the resist layer when the template is pressed, so that a defect may be generated in a next shot to be processed.

### DESCRIPTION OF THE DRAWINGS

FIG. 1 is a diagram showing a configuration example of an imprint device used in a process of manufacturing a semiconductor device according to a first embodiment.

FIGS. 2A and 2B are views showing an example of a wafer obtained in the process of manufacturing a semiconductor device according to the first embodiment.

FIGS. 3A and 3B are views showing a process of forming the wafer in the process of manufacturing the semiconductor device according to the first embodiment.

FIGS. 4A to 4C are views showing a step of forming a liquid film of a first resist material on the wafer in the process of manufacturing the semiconductor device according to the first embodiment.

FIGS. 5A and 5B are views showing an imprint processing performed on the wafer in the process of manufacturing the semiconductor device according to the first embodiment.

FIGS. 6A to 6D are views showing the imprint processing performed on the wafer in the process of manufacturing the semiconductor device according to the first embodiment.

FIGS. 7A to 7D are views showing a process of processing a film to be processed in the process of manufacturing the semiconductor device according to the first embodiment.

FIGS. 8A to 8D are views showing a process performed on a wafer in a process of manufacturing a semiconductor device according to a modification example of the first embodiment.

FIG. 9 is a diagram showing a configuration example of an imprint device used in a process of manufacturing a semiconductor device according to second embodiment.

FIG. 10 is a schematic view showing an example of a coating ratio map used in the process of manufacturing a semiconductor device according to the second embodiment.

FIGS. 11A to 11D are views showing a process performed on a wafer in a process of manufacturing a semiconductor device according to the second embodiment.

FIGS. 12A and 12B are views showing a process performed on a wafer in a process of manufacturing a semiconductor device according to a modification example of the embodiment.

FIGS. 13A to 13D are views showing a part of a process of manufacturing a semiconductor device according to a comparative example.

FIG. 14 is a view showing a part of the process of manufacturing the semiconductor device according to the comparative example.

FIGS. 15A and 15B are views showing a part of the process of manufacturing the semiconductor device according to the comparative example.

### DETAILED DESCRIPTION

Embodiments provide an imprint method capable of reducing defects and a method for manufacturing a semiconductor device.

In general, according to one embodiment, the imprint method includes forming a liquid film of a first photocurable resin to have a substantially flat upper surface on a central region of a substrate, depositing droplets of a second photocurable resin on an outer peripheral region of the substrate, pressing a template against the first photocurable resin and the second photocurable resin, irradiating the first photocurable resin and the second photocurable resin with light to cure the first photocurable resin and the second photocurable resin, and releasing the template from the first photocurable resin and the second photocurable resin to expose a pattern on the substrate, that is formed by the cured first photocurable resin and the cured second photocurable resin.

Hereinafter, embodiments will be described in detail with reference to the drawings. Further, the present disclosure is not limited to the following embodiment. Elements in the following embodiments include those that may be easily assumed by those skilled in the art or those that are substantially the same.

### Embodiment 1

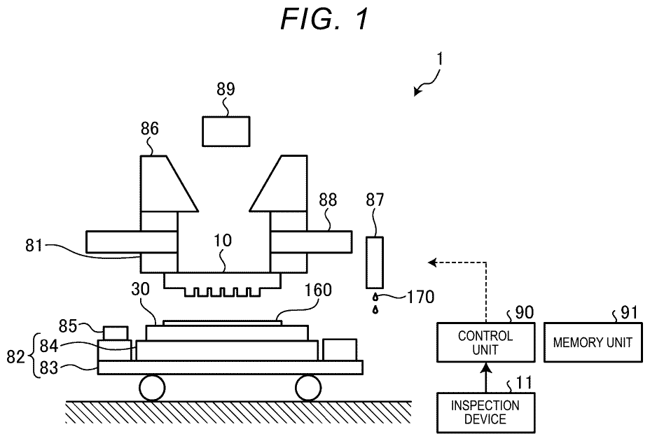

Hereinafter, an embodiment 1 will be described in detail with reference to FIG. 1 and FIGS. 2A to 6D.

FIG. 1 is a diagram showing a configuration example of an imprint device 1 used in the embodiment 1. As shown in FIG. 1, the imprint device 1 includes a template stage 81, a wafer stage 82, a reference mark 85, an alignment sensor 86, a droplet fall device 87, a stage base 88, a light source 89, a control unit 90, and a memory unit 91.

In addition, the imprint device 1 is provided with a template 10 that transfers a pattern onto a substrate, e.g., wafer 30. The template 10 is made of a transparent member such as quartz.

In addition, in the imprint device 1 in FIG. 1, the wafer 30 is prepared prior to an imprint processing. A first resist material 160 is formed in a central region on the wafer 30. The imprint device 1 executes the imprint processing by depositing a second resist material 170 onto an outer peripheral region of the wafer 30 and transferring the pattern of the template 10 to the first resist material 160 and the second resist material 170.

In addition, an inspection device 11 is connected to the control unit 90 of the imprint device 1. The inspection device 11 is a device that performs a predetermined inspection on the wafer 30 before the imprint processing, that is, after the first resist material 160 is formed. The inspection device 11 is, for example, an optical microscope. The inspection device 11 transmits measurement data generated thereby as an inspection result to the control unit 90. The inspection device 11 stores the measurement data in the memory unit 91.

The wafer stage 82 includes a wafer chuck 84 and a main body 83. The wafer chuck 84 fixes the wafer 30 to a predetermined position on the main body 83. The reference mark 85 is provided on the wafer stage 82. The reference mark 85 is used for alignment when loading the wafer 30 onto the wafer stage 82.

The wafer 30 is placed on the wafer stage 82, and the wafer stage 82 moves in a plane parallel to the placed wafer 30 (e.g., in a horizontal plane). Before the second resist material 170 is dropped onto the outer peripheral region of the wafer 30, the wafer stage 82 moves the wafer 30 to a lower side of the droplet fall device 87 described later, and when the pattern is transferred to the first resist material 160 and the second resist material 170 on the wafer 30, the wafer stage 82 moves the wafer 30 to a lower side of the template 10.

The stage base 88 supports the template 10 by way of the template stage 81 and moves in a direction perpendicular to the placed wafer (e.g., an up-down or vertical direction). As a result, the template 10 is pressed against the wafer 30.

The alignment sensor 86 is provided on the stage base 88. The alignment sensor 86 detects a position of the wafer 30 or a position of the template 10 based on alignment marks provided on the wafer 30 and the template 10.

The droplet fall device 87 causes a droplet of the second resist material 170 to fall on the wafer 30 by an ink jet method. The inkjet head provided in the droplet fall device 87 has a plurality of micropores. The droplet fall device 87 causes the droplet of the second resist material 170 to fall from the plurality of micropores to a predetermined position on the wafer 30. The droplet fall device 87 is capable of depositing the droplet of the second resist material 170 with a positioning accuracy of ±20 μm to 30 μm. In this way, the droplet fall device 87 can form the droplet of the second resist material 170 on the wafer 30 with relatively high accuracy. The second resist material 170 is a chemical solution such as a resist that is cured when irradiated with light, e.g., a photocurable resin.

The light source 89 is, for example, a device that emits ultraviolet rays, and is provided above the stage base 88. The light source 89 emits light from above the template 10 when the template 10 is pressed against the first resist material 160 and the second resist material 170. As a result of being irradiated with the light, the first resist material 160 and the second resist material 170 are cured.

The control unit 90 controls each part of the imprint device 1. The control unit 90 includes, for example, a computer that performs a predetermined control process according to a program, and includes a central processing unit (CPU), a read only memory (ROM), a random access memory (RAM), and the like.

Specifically, the control unit 90 controls the template stage 81, the wafer stage 82, the droplet fall device 87, the stage base 88, the light source 89, and the like. In addition, the control unit 90 refers to the measurement data acquired from the above-described inspection device 11 in controlling each unit.

The memory unit 91 is, for example, a semiconductor memory device, which may be volatile or non-volatile, or a magnetic storage device, and stores the measurement data acquired by the inspection device 11. In addition, the memory unit 91 stores the measurement data and information about a resist-applying device or the like that applied resist to the wafer 30, in association with each other.

### Method for Manufacturing Semiconductor Device

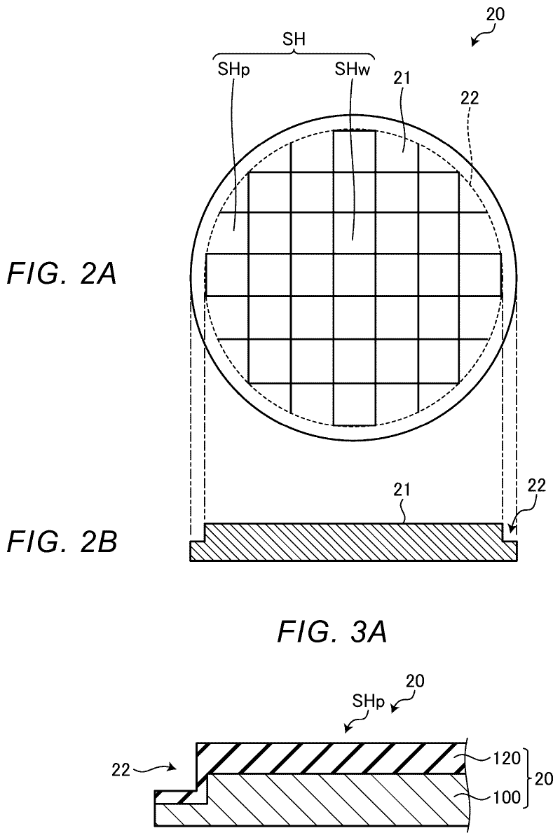

Next, an example of a method for manufacturing a semiconductor device according to the embodiment 1, including an imprint processing using the imprint device 1 will be described using FIGS. 2A to 7D. The method for manufacturing the semiconductor device according to the embodiment 1 includes an imprint processing on the wafer 30.

First, a process of forming the wafer 30 to be subjected to the imprint processing will be described.

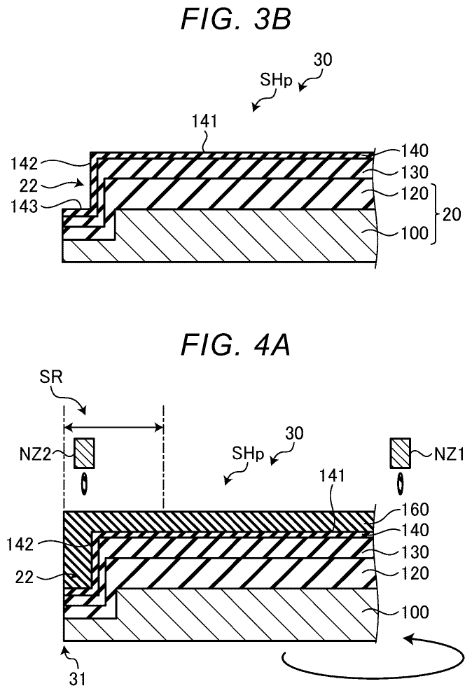

FIGS. 2A and 2B are views showing an example of a wafer 20 obtained in a process of manufacturing the semiconductor device according to the embodiment 1. FIG. 2A is a plan view of the wafer 20, and FIG. 2B is a cross-sectional view of the wafer 20. The wafer 20 becomes the wafer 30 through a process of FIGS. 3A and 3B described later.

As shown in FIGS. 2A and 2B, the wafer 20 has an element forming region 21 and a bevel region 22.

The bevel region 22 is an annular region that is formed by a step at an outer end region (an outer peripheral portion) of the wafer 20. A width of the bevel region 22 is, for example, 1.5 mm, and a height of the step is, for example, 100 nm.

The element forming region 21 is a substantially circular region inside the bevel region 22 of the wafer 20. A plurality of shots SH (SHw, SHp) formed through a plurality of manufacturing steps are formed in the element forming region 21. Each of the shots SH is a unit of processing in each manufacturing step of the semiconductor device. For example, during the imprint processing, one shot SH is processed each time the template 10 is pressed.

Among the shots SH, a normal shot SHw is a shot in which an entire rectangular region is provided in the element forming region 21. In addition, among the shots SH, a partial shot SHp is a shot in which only a part thereof comes into contact with the template 10. That is, the partial shot SHp is located in the outer peripheral portion of the element forming region 21 and is adjacent to the bevel region 22.

FIGS. 3A and 3B are views showing a step of forming the wafer 30 in a process of manufacturing a semiconductor device according to the embodiment 1.

FIG. 3A shows a cross-sectional view of the predetermined partial shot SHp and the wafer 20 in the bevel region 22. In addition, FIG. 3B shows a cross-sectional view of the predetermined partial shot SHp and the wafer 30 in the bevel region 22.

As shown in FIG. 3A, the wafer 20 includes a film to be processed 120 on a silicon substrate 100. The film to be processed 120 is a film to be subjected to processing, and is, for example, a single layer film such as a silicon oxide film or a silicon nitride film, or a stacked film in which a plurality of films are stacked.

As shown in FIG. 3B, a spin on carbon (SOC) film 130 is formed on the film to be processed 120. The SOC film 130 is a film formed by, for example, a spin coating method, and is an organic film containing carbon.

Next, a spin on glass (SOG) film 140 is formed on the SOC film 130. The SOG film 140 is a film formed by, for example, the spin coating method and is an inorganic film such as a silicon oxide film.

The wafer 30 to be subjected to the imprint processing is formed by the above-described processing.

At this time, the SOC film 130 and the SOG film 140 are formed to cover the surfaces of the element forming region 21 and the bevel region 22, and a surface of a step portion connecting the element forming region 21 and the bevel region 22. Therefore, the SOG film 140 has a flat surface portion 141 along the element forming region 21, a side surface portion 142 facing an outside of the wafer 30 along a step of the bevel region 22, and a bottom surface portion 143 that extends from a lower end of the side surface portion 142 toward an end portion 31 of the wafer 30. The flat surface portion 141 is a substantially circular region of which an edge portion is defined by the side surface portion 142. After that, the plurality of shots SH are processed on the flat surface portion 141 through a plurality of manufacturing steps.

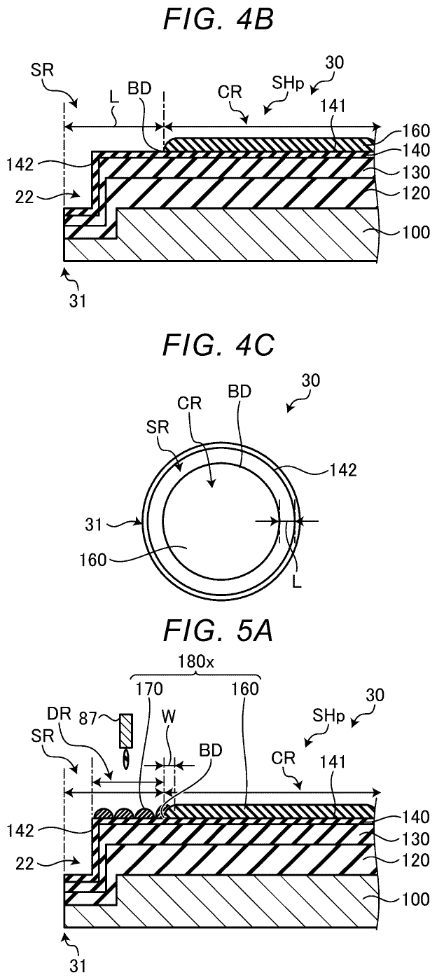

FIGS. 4A to 4C are views showing a step of forming a liquid film of the first resist material 160 on the wafer 30 in the process of manufacturing the semiconductor device according to the embodiment 1.

FIGS. 4A and 4B show a cross-sectional view of the predetermined partial shot SHp and the wafer 30 in the bevel region 22. In addition, FIG. 4C is a plan view of the wafer 30 corresponding to FIG. 4B. In each of FIGS. 4A and 4B, a side of the end portion 31 of the wafer 30 is referred to as an outside of the wafer 30, and an opposite side is referred to as an inside of the wafer.

FIG. 4A is a view showing a step of forming the first resist material 160 on the wafer 30, and shows a step following the processing step of FIG. 3B. First, as shown in FIG. 4A, the first resist material 160 is applied to the flat surface portion 141 of the SOG film 140 using a resist-applying device (not shown). The spin coating method is used for applying the first resist material 160.

The spin coating method is a method for forming a liquid film by supplying a droplet to a vicinity of a center of a substrate and rotating the substrate to spread the droplet to the outer peripheral portion of the substrate. In the example of FIGS. 4A to 4C, the first resist material 160 is supplied from a nozzle NZ1 to a vicinity of a center of the wafer 30, and the wafer 30 is rotated. As a result, the first resist material 160 is spread, and the SOG film 140 is covered with the liquid film of the first resist material 160.

It is assumed that the first resist material 160 is a chemical solution such as a resist that is cured when irradiated with light and has the same composition as that of the second resist material 170. The first resist material 160 is, for example, a photocurable resin.

Here, the reason why the spin coating method is used for forming the liquid film of the first resist material 160 will be described. In the spin coating method, since the droplet supplied to the vicinity of the center of the substrate is spread by a centrifugal force, a surface of the formed liquid film is frequently substantially flat. Therefore, when the template 10 is pressed against the above-described surface of the liquid film, an amount of air interposed between the template 10 and the surface of the liquid film can be reduced. Therefore, a filling of a concave portion of the template 10 with the liquid film proceeds quickly without being inhibited by the air, and as a result, a processing time of the imprint processing can be shortened.

Returning to FIG. 4A, a device that is not shown supplies an organic solvent such as a thinner from a nozzle NZ2 to an outer peripheral portion SR of the wafer 30 while maintaining a rotation of the wafer 30. As a result, as shown in FIGS. 4B and 4C, in the outer peripheral portion SR, the first resist material 160 is dissolved and removed, a part of the SOG film 140 is exposed, and a peripheral edge portion BD of the first resist material 160 is formed. The peripheral edge portion BD is located inside the side surface portion 142 of the SOG film 140. A width L from the end portion 31 to the peripheral edge portion BD, of the wafer 30 is, for example, 2 mm to 3 mm.

With the above-described processing, the liquid film of the first resist material 160 is formed in the central region CR of the wafer 30. The central region CR is a substantially circular region of which edge is defined by the peripheral edge portion BD.

Next, the wafer 30 on which the liquid film of the first resist material 160 is formed, is transported to the inspection device 11 (FIG. 1).

The inspection device 11 inspects the wafer 30. Specifically, for example, the inspection device 11 captures an image of a region including at least the outer peripheral portion SR of the wafer 30. The inspection device 11 specifies location information of the peripheral edge portion BD and the side surface portion 142 based on the captured image. The inspection device 11 generates measurement data in which the location information of the specified peripheral edge portion BD and location information of the side surface portion 142 are associated with each other. The inspection device 11 transmits the measurement data to the control unit 90.

Next, the wafer 30 on which the inspection by the inspection device 11 has been completed is transported to the imprint device 1 (FIG. 1).

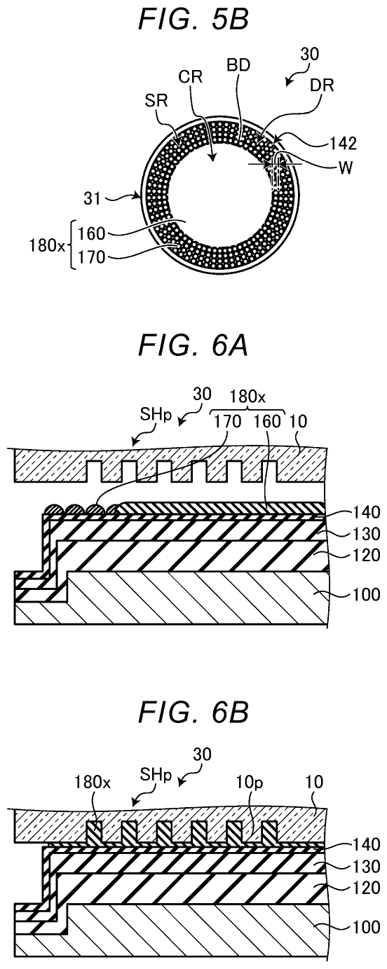

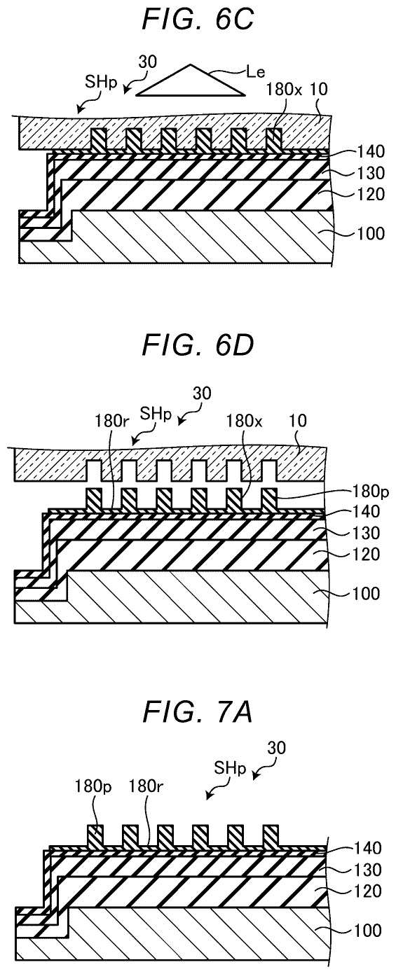

FIGS. 5A to 6D are views showing an imprint processing performed on the wafer 30 in the process of manufacturing the semiconductor device according to the embodiment 1.

FIG. 5A and FIGS. 6A to 6D show cross-sectional views of the predetermined partial shot SHp and the wafer 30 in the bevel region 22. In addition, FIG. 5B is a plan view of the wafer 30 corresponding to FIG. 5A. In each of FIG. 5A and FIGS. 6A to 6D, the side of the end portion 31 of the wafer 30 is referred to as the outside of the wafer 30, and the opposite side is referred to as the inside of the wafer.

FIG. 5A is a view showing a step of forming the second resist material 170 on the wafer 30, and shows a step following the processing step of FIG. 4B. Before FIG. 5A, the control unit 90 places the wafer 30 transported from the inspection device 11 on the wafer stage 82 (FIG. 1). Then, the control unit 90 controls the wafer stage 82 to move the wafer 30 below the droplet fall device 87.

The control unit 90 controls the droplet fall device 87 to deposit the droplet of the second resist material 170 on the outer peripheral region DR of the flat surface portion 141 of the SOG film 140. Specifically, the control unit 90 controls the droplet fall device 87 to deposit the droplet of the second resist material 170 on the outside of the first resist material 160. As a result, a resist layer 180x including the first resist material 160 and the second resist material 170, is formed on the SOG film 140.

At this time, the control unit 90 determines the outer peripheral region DR based on the measurement data acquired from the inspection device 11. Specifically, the control unit 90 specifies a region from the side surface portion 142 to the peripheral edge portion BD as the outer peripheral region DR that is a deposition target of the droplet of the second resist material 170, based on the location information of the peripheral edge portion BD and the location information of the side surface portion 142 of the SOG film 140 included in the measurement data.

In addition, as shown in FIGS. 5A and 5B, the control unit 90 also drops the second resist material 170 in an annular shape in a region inside a boundary portion between the central region CR and the outer peripheral region DR within a width W. The width W is not limited to a particular width. However, in one example, the width W is assumed to be equal to or less than a width of one droplet of the second resist material 170. The width of one droplet is, for example, 10 μm or less.

As a result, the first resist material 160 and the second resist material 170 overlap each other vertically in a vicinity of the boundary portion between the central region CR and the outer peripheral region DR. As a result, the continuous resist layer 180x is formed without generating a gap between the first resist material 160 and the second resist material 170.

The above-described specific processing of the outer peripheral region DR by the control unit 90 may be performed at a predetermined timing after the control unit 90 acquires the measurement data from the inspection device 11 and before the control unit 90 starts to deposit the droplet of the second resist material 170.

When the deposition of the droplet of the second resist material 170 is completed, the control unit 90 moves the wafer 30 below the template 10 as shown in FIG. 6A.

Next, as shown in FIG. 6B, the control unit 90 presses the template 10 against the resist layer 180x. Then, the resist layer 180x is steadily filled in the concave portions of the pattern 10p to follow an uneven portion of the pattern 10p provided in the template 10.

As shown in FIG. 6C, when the concave portion of the template 10 is filled with the resist layer 180x, the control unit 90 irradiates the resist layer 180x with an ultraviolet light Le from above the template 10 while maintaining a state in which the template 10 is pressed against the resist layer 180x. The ultraviolet light Le has a wavelength in a range of wavelengths at which the resist layer 180x is photosensitive. The ultraviolet light Le is transmitted through the transparent template 10 and irradiates the resist layer 180x. As a result, the resist layer 180x is cured. The irradiation amount of the ultraviolet ray Le at this time is preferably an irradiation amount in which the resist layer 180x is completely cured. The complete curing referred to herein means a state in which the resist layer 180x is cured to a degree that the resist layer 180x can be mold-released from the template 10 or to a degree that the resist layer 180x functions as an etching mask for the SOG film 140.

As shown in FIG. 6D, the control unit 90 mold-releases the template 10 from the resist layer 180x. As a result, a patterned resist 180p is formed. The patterned resist 180p has a pattern in which the pattern 10p of the template 10 is inverted. In addition, a resist residual film 180r is formed in the concave portion between the convex patterns of the patterned resist 180p. The reason is that, when the template 10 is pressed, the projection portion of the pattern 10p of the template 10 is maintained slightly above a bottom surface of the resist layer 180x.

As described above, the imprint processing performed on the predetermined partial shot SHp of the wafer 30 is ended.

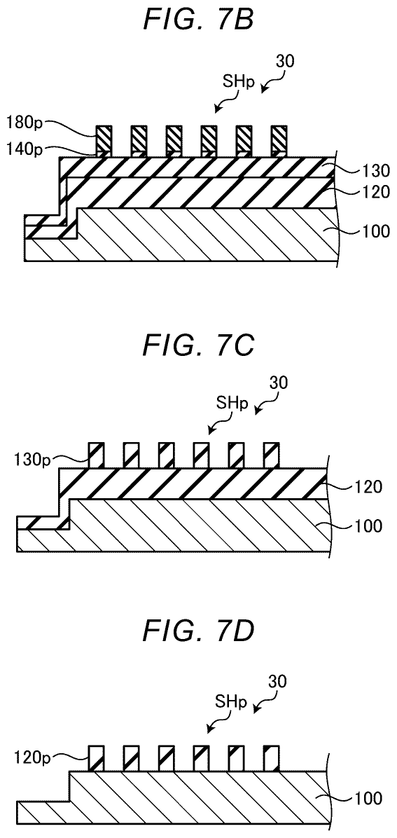

FIGS. 7A to 7D are views showing a process of processing the film to be processed 120 in the process of manufacturing the semiconductor device according to the embodiment 1.

FIGS. 7A to 7D show cross-sectional views of the predetermined partial shot SHp and the wafer 30 in the bevel region 22.

As shown in FIG. 7A, the patterned resist 180p formed by the imprint processing has the above-described resist residual film 180r. Therefore, first, the resist residual film 180r is removed by resist etching, and the SOG film 140 is etched using the patterned resist 180p as a mask. Then, as shown in FIG. 7B, the SOG pattern 140p is formed.

Next, the SOG pattern 140p is used as a mask to etch the SOC film 130, so that a SOC pattern 130p is formed as shown in FIG. 7C. The patterned resist 180p is an organic film similar to the SOC pattern 130p. Therefore, in the above-described process, the patterned resist 180p is removed.

Next, the SOC pattern 130p is used as a mask to etch the film to be processed 120, so that a patterned film to be processed 120p is formed as shown in FIG. 7C. During this step, the SOC pattern 130p is removed by ashing using oxygen plasma.

As described above, the film to be processed 120p on which a pattern is formed can be obtained. Thereafter, the semiconductor device of the embodiment 1 is manufactured through various manufacturing steps.

### Comparative Example

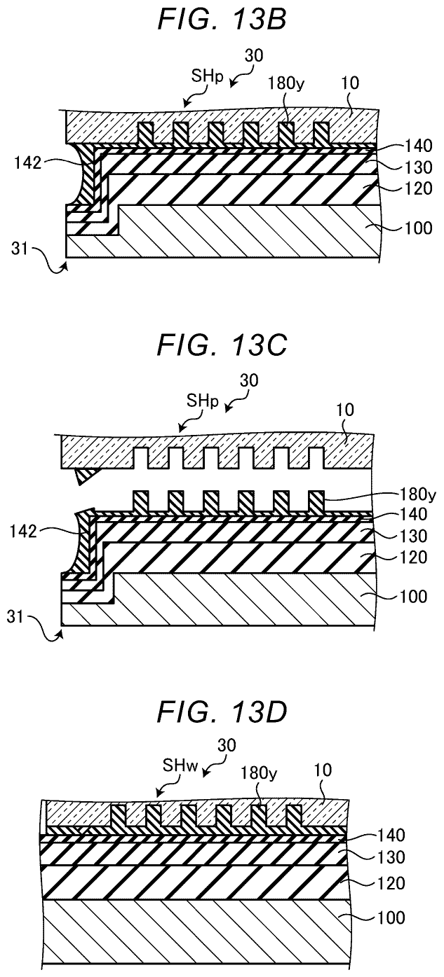

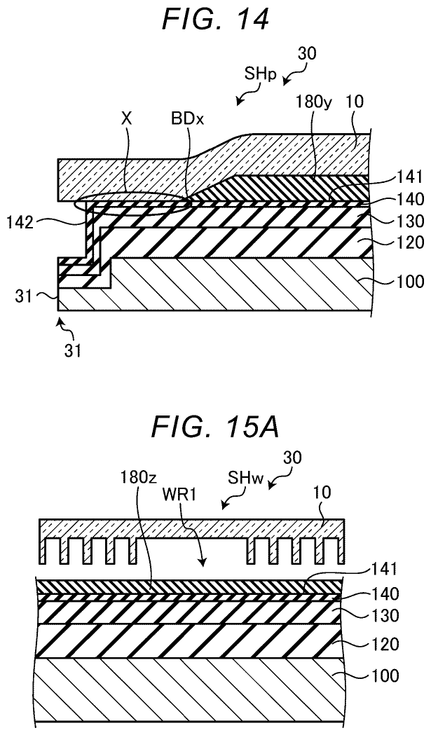

Here, a method for manufacturing a semiconductor device of a comparative example of the embodiment 1 will be described with reference to FIGS. 13A, 13B, and 14. FIGS. 13A, 13B, and 14 are views showing a part of the process of manufacturing the semiconductor device according to the comparative example.

FIGS. 13A to 13C show a cross-sectional view of the predetermined partial shot SHp after the resist layer 180y is formed on the wafer 30 and in the bevel region 22. In addition, FIG. 13D is a cross-sectional view of the normal shot SHw imprint-processed after the partial shot SHp. In each of FIGS. 13A to 13C, the side of the end portion 31 of the wafer 30 is referred to as the outside of the wafer 30, and the opposite side is referred to as the inside of the wafer.

In the method for manufacturing the semiconductor device of the comparative example, the resist layer 180y is formed by spin coating. At this time, the position of the peripheral edge portion BDx of the resist layer 180y may vary in a circumferential direction of the wafer 30. The reason is that, a supply position of the organic solvent with respect to the wafer 30 varies in the circumferential direction. A variation in the supply position of the organic solvent with respect to the wafer 30 described above, may be caused by a rotation of the wafer 30 that is eccentric.

Specifically, as shown in FIG. 13A, the peripheral edge portion BDx of the resist layer 180y may protrude outward from the side surface portion 142 by, for example, about 50 μm. As shown in FIG. 13B, when the template 10 is pressed against the wafer 30, as shown in FIG. 13C, when the template 10 is mold-released from the wafer 30, a part of the resist layer 180y may adhere to the template 10, so that the template 10 may be contaminated. When the imprint processing is performed on the normal shot SHw of the next processing target using the template 10, as shown in FIG. 13D, the contaminated portion of the template 10 may be transferred to the shot SH, causing what is known as a succession defect.

On the other hand, for example, as shown in FIG. 14, the peripheral edge portion BDx of the resist layer 180y may be located inside the side surface portion 142. When the template 10 is pressed against the above-described wafer 30, the template 10 and the flat surface portion 141 of the SOG film 140 may come into contact in a region X outside the peripheral edge portion BDx. At this time, a shearing force generated between the template 10 and the SOG film 140 may deteriorate an alignment accuracy of the template 10. As a result, defects such as poor formation of a pattern may occur.

The variation in the position of the peripheral edge portion BDx as described above is, for example, within ±100 μm in the circumferential direction of the wafer 30. In addition, the above-described variation in the position of the peripheral edge portion BDx is usually different depending on the resist-applying device. That is, for example, the positions of the peripheral edge portions BDx of the wafer 30 processed by the same resist-applying device are usually the same.

### Operation and Effect

According to the imprint method of the embodiment 1, the first resist material 160 is applied to the central region CR of the wafer 30 to form the liquid film of the first resist material 160, and the droplet of the second resist material 170 is deposited on the outer peripheral region DR of the wafer 30. Then, the template 10 is pressed against the resist layer 180 formed of the first resist material 160 and the second resist material 170. As a result, a pattern is formed.

As described above, by disposing the droplet of the second resist material 170 in the outer peripheral region DR of the wafer 30, the resist layer 180x to be subjected to the imprint processing can be accurately formed on the flat surface portion 141 which is inside the side surface portion 142 of the SOG film 140, that is, the processing target of the shot SH. As a result, contamination of the template 10 and deterioration of the alignment accuracy are reduced, and thus defects can be reduced, such as succession defects and pattern formation defects. In addition, as a result, it is also possible to improve the yield of the semiconductor and to reduce the manufacturing cost.

In addition, in the embodiment 1, after the first resist material 160 is applied, the droplet of the second resist material 170 is deposited on the outside of the first resist material 160 as the outer peripheral region DR. As described above, after the first resist material 160 is applied, the process of depositing the droplet of the second resist material 170 and the process of transferring the template 10 are continuously performed in the same imprint device 1. As a result, it is possible to shorten the processing time required for manufacturing the semiconductor device.

In addition, the location information of the peripheral edge portion BD of the first resist material 160 is acquired, and the droplet of the second resist material 170 is deposited based on the location information. As described above, since the droplet of the second resist material 170 can be deposited after the location information of the first resist material 160 is understood, the resist layer 180x can be formed more densely and accurately on the flat surface portion 141. As a result, the defects can be further reduced.

### Modification Example

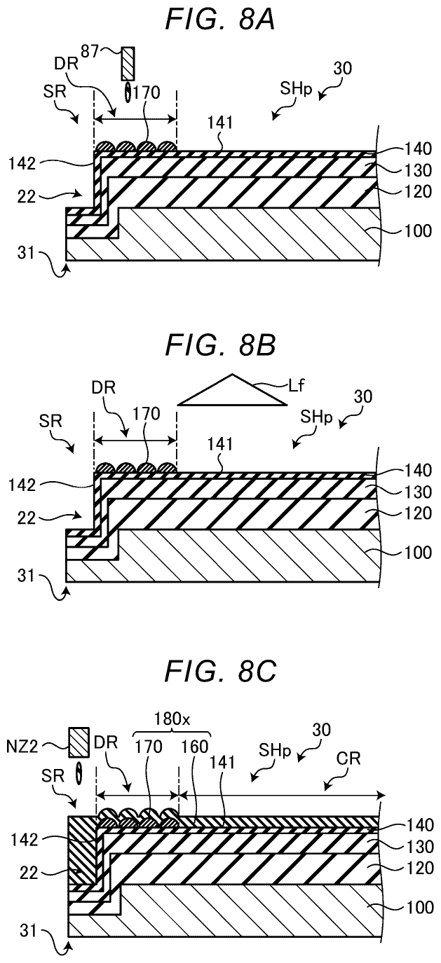

A modification example of the embodiment 1 will be described in detail with reference to FIGS. 8A to 8D. In the imprint method of the modification example, the time at which the coating of the first resist material 160 is performed relative to the deposition of the droplets of the second resist material 170, is different from that of the above-described embodiment. In addition, below, the same symbol is attached to the same configuration as that in described-above embodiment 1, and the description thereof may be omitted.

FIGS. 8A to 8D are views showing a process of performing a process on the wafer 30 in the process of manufacturing the semiconductor device according to the modification example of the embodiment 1. FIGS. 8A and 8B show a cross-sectional view of the predetermined partial shot SHp and the wafer in the bevel region 22.

Before the process of FIGS. 8A to 8D, the wafer 30 subjected to the process of FIG. 3B is transported to the imprint device 1.

Next, as shown in FIG. 8A, the control unit 90 controls the droplet fall device 87 to deposit the droplet of the second resist material 170 on the outer peripheral region DR of the wafer 30.

Then, the control unit 90 determines the outer peripheral region DR described above, based on the measurement data stored in the memory unit 91.

As described above, the memory unit 91 previously stores the measurement data of the wafer 30 and the information regarding the resist-applying device that processed the wafer 30 in association with each other. The control unit 90 acquires the measurement data corresponding to the resist-applying device used in the following step from the memory unit 91, and determines the outer peripheral region DR based on the measurement data. The reason is that, the positions of the peripheral edge portions BDx of the wafers 30 processed by the same resist-applying device are usually the same. In this manner, the control unit 90 determines the position of the peripheral edge portion BDx of the first resist material 160 to be applied in the following step, based on the measurement data, and then controls the droplet fall device 87 to deposit the droplet of the second resist material 170.

Next, as shown in FIG. 8B, the second resist material 170 is irradiated with an ultraviolet light Lf using the light source 89. The ultraviolet light Lf has a wavelength in a range of wavelengths at which the second resist material 170 is photosensitive. The irradiation amount of the ultraviolet ray Lf at this time is preferably an irradiation amount that causes the second resist material 170 to be semi-cured. The semi-curing referred to herein means a state in which a viscosity of the second resist material 170 is increased and the second resist material 170 is not completely cured. As a result, a volatilization of the second resist material 170 is reduced, and a deterioration thereof can be inhibited. In addition, the second resist material 170 becomes insoluble in the first resist material 160 and an organic solvent, which will be described later.

Next, the wafer 30 on which the deposition of the second resist material 170 is completed, is transported to the resist-applying device (not shown) described above. Then, as shown in FIG. 8C, the first resist material 160 is applied onto the flat surface portion 141 of the SOG film 140 to form the liquid film.

At this time, the first resist material 160 covers the droplet of the second resist material 170. Therefore, the second resist material 170 in the outer peripheral region DR is exposed by supplying the organic solvent to the outer peripheral portion SR using the nozzle NZ2. As a result, as shown in FIG. 8D, the liquid film of the first resist material 160 is formed in the central region CR that is inside the droplet of the second resist material 170.

In addition, as shown in FIG. 8D, the control unit 90 supplies the organic solvent to a region that is outside the boundary portion between the central region CR and the outer peripheral region DR by a predetermined width. As a result, the first resist material 160 and the second resist material 170 overlap each other vertically in a vicinity of the boundary portion between the central region CR and the outer peripheral region DR. The predetermined width is, for example, 100 μm or more.

After that, the process after FIG. 6A of the embodiment 1 described above is performed.

### Operation and Effect

According to the method for manufacturing the semiconductor device of the modification example, since the resist layer 180x can be formed densely and accurately on the flat surface portion 141, defects can be reduced.

### Embodiment 2

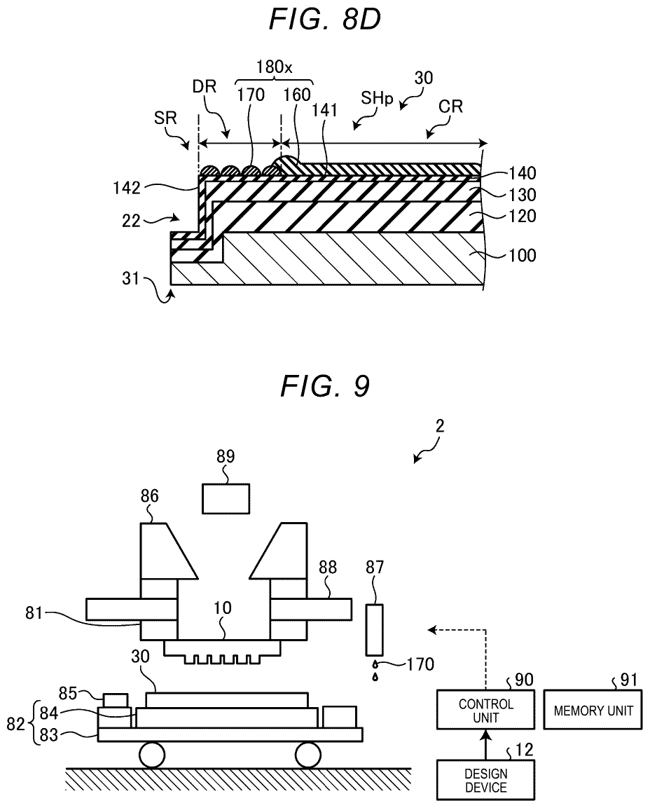

Hereinafter, an embodiment 2 will be described in detail with reference to FIGS. 9, 10, and 11A to 11D.

The method for manufacturing the semiconductor device of the embodiment 2 is different from that of the embodiment 1 in that a deposition position of the droplet of the second resist material 170 is determined based on the layout of the template 10. In addition, in the description below, the same symbol is attached to the same configuration as that in above-described embodiment 1, and the description thereof may be omitted.

FIG. 9 is a diagram showing a configuration example of an imprint device 2 according to the embodiment 2. As shown in FIG. 9, a design device 12 is connected to the control unit 90 of the imprint device 2.

The design device 12 generates design information such as a design of the semiconductor device and a layout of the template 10 that is based on the design of the semiconductor device at the beginning of the manufacturing step of the semiconductor device. The design information includes information regarding the layout of the template 10 and includes dimensions and a deposition position of the uneven portion of the pattern 10p provided in the template 10. In addition, the design information includes a coating ratio map M to be described later. The design device 12 transmits the above-described design information to the control unit 90 of the imprint device 1.

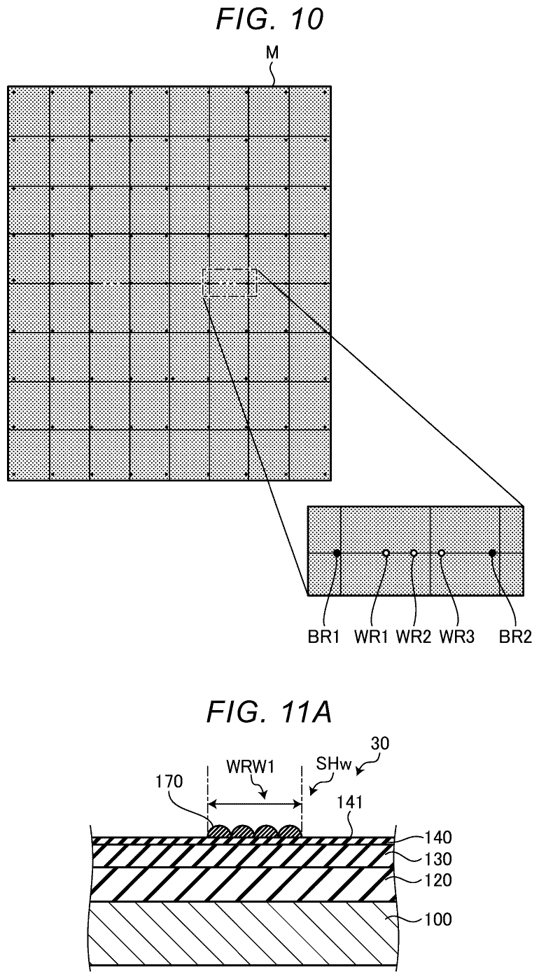

FIG. 10 is a schematic view showing an example of the coating ratio map M according to the embodiment 2. The coating ratio map M indicates a magnitude of the coating ratio of the template 10 in color. For example, in the coating ratio map M, the regions WR1 to WR3 indicated by white color indicate that the regions have the coating ratio equal to or less than a predetermined threshold value. On the other hand, regions BR1 and BR2 indicated by black color indicate that the regions have the coating ratio greater than the predetermined threshold value. The predetermined threshold value is, for example, 20%. That is, for example, the regions WR1 to WR3 are regions where the coating ratio is 20% or less. The coating ratio indicates a ratio of an area occupied by the concave portion to a predetermined area in which the pattern 10p of the template 10 is formed. For example, a small coating ratio indicates that the area of the concave portion per predetermined area is large.

The control unit 90 determines the deposition position of the second resist material 170 based on the above-described coating ratio map M.

### Method for Manufacturing Semiconductor Device

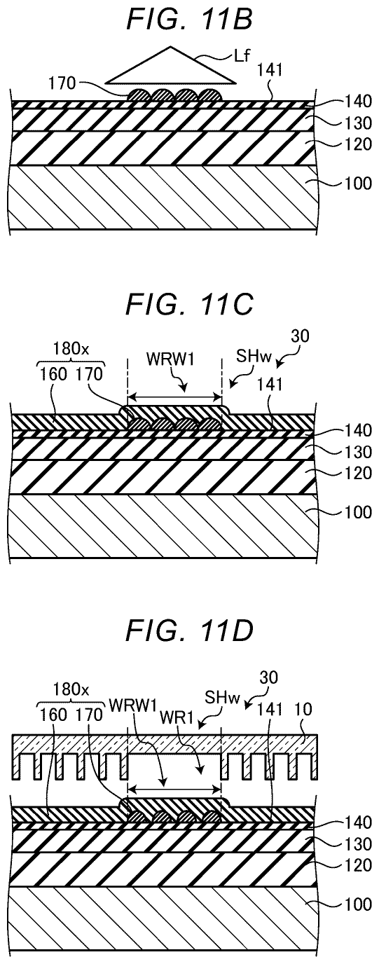

Next, an example of a method for manufacturing a semiconductor device including an imprint processing using the imprint device 2 of the embodiment 2 will be described with reference to FIGS. 11A to 11D.

FIGS. 11A to 11D are views showing a process performed on the wafer 30 in the process of manufacturing the semiconductor device according to the embodiment 2. FIGS. 11A to 11D show cross-sectional views of the wafer in the predetermined normal shot SHw. In addition, also in the embodiment 2, the processing of FIGS. 3A and 3B and the processing after FIG. 6B in embodiment 1 are performed.

First, before the process of FIGS. 11A to 11D, the wafer 30 after the process of FIG. 3B is transported to the imprint device 1.

As shown in FIG. 11A, the control unit 90 controls the droplet fall device 87 to deposit the droplet of the second resist material 170 on the flat surface portion 141 of the SOG film 140.

At this time, the control unit 90 determines the deposition position of the droplet of the second resist material 170 on the flat surface portion 141 based on the coating ratio map M. Specifically, for example, the control unit 90 determines a region WRW1 on the flat surface portion 141 corresponding to the region WR1 of the template 10 having the coating ratio equal to or less than the predetermined threshold value, as the deposition position of the droplet of the second resist material 170.

Next, as shown in FIG. 11B, the second resist material 170 is irradiated with the ultraviolet light Lf using the light source 89. The irradiation amount of the ultraviolet ray Lf at this time is preferably an irradiation amount that causes the second resist material 170 to be semi-cured.

Next, the wafer 30 on which the irradiation with the ultraviolet light Lf is completed, is transported to the resist-applying device (not shown). Then, as shown in FIG. 11C, the first resist material 160 is applied onto the wafer 30 to form the liquid film. As a result, the flat surface portion 141 of the second resist material 170 including the droplet is covered with the liquid film of the first resist material 160. In this manner, the resist layer 180x formed of the first resist material 160 and the second resist material 170 is formed.

At this time, in the region WRW1, the second resist material 170 and the first resist material 160 overlap vertically. As a result, the formation amount of the resist layer 180x in the region WRW1 is larger than that in the region other than the region WRW1.

Next, the control unit 90 moves the wafer 30 below the template 10 as shown in FIG. 11D. Then, the region WRW1 on the flat surface portion 141 and the region WR1 of the template 10 face each other in the up-down direction. After that, when the template 10 is pressed against the resist layer 180x, the resist layer 180x in the region WRW1 is filled in the concave portion of the region WR1 of the template 10.

After that, the process after FIG. 6B of the above-described embodiment is performed.

### Comparative Example

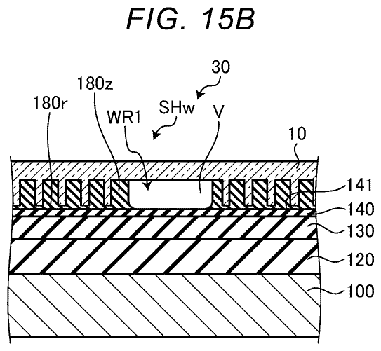

A method for manufacturing a semiconductor device of a comparative example of the embodiment 2 will be described with reference to FIGS. 15A and 15B. FIGS. 15A and 15B are views showing a part of a process of manufacturing a semiconductor device according to a comparative example.

FIGS. 15A and 15B show cross-sectional views of the wafer in the predetermined normal shot SHw in which a resist layer 180z of the comparative example is formed.

As shown in FIG. 15A, a film thickness of the resist layer 180z formed by the spin coating method is substantially uniform on the flat surface portion 141. As described above, when the template 10 is pressed against the wafer 30, as shown in FIG. 15B, for example, in the region WR1 where the coating ratio of the template 10 is low, the concave portion thereof may not be sufficiently filled with the resist layer 180z, and a void V may be formed in the resist layer 180z. The reason is that, the area of the concave portion per predetermined area of the template 10 is large, and thus a filling amount of the resist layer 180z in the concave portion is insufficient. The above-described void V may cause defects such as pattern defects.

Therefore, for example, a thickness of the resist layer 180z may be increased for the purpose of increasing the filling amount of the resist layer 180z in the region WR1. Meanwhile, at this time, a thickness of the resist residual film 180r may be increased when the template 10 is pressed. As a result, a process margin when processing the film to be processed 120 may be reduced.

### Operation and Effect

In the imprint method of the embodiment 2, the deposition position of the droplet of the second resist material 170 is determined based on the coating ratio of the template 10 that is transferred to the wafer 30. The first resist material 160 is applied to the wafer 30 on which the second resist material 170 is disposed, and the template 10 is pressed against the resist layer 180x formed of the first resist material 160 and the second resist material 170. As a result, a pattern is formed.

As a result, the concave portion of the template 10 can be sufficiently filled with the resist layer 180 regardless of the coating ratio of the template 10, so that defects such as pattern defects can be reduced. In addition, as a result, it is also possible to improve the yield of the semiconductor and to reduce the manufacturing cost.

In addition, the droplet of the second resist material 170 is deposited at a position of the wafer 30 corresponding to a location where the coating ratio is equal to or less than the predetermined threshold value. As a result, the resist layer 180 can be sufficiently filled in the concave portion of the region where the coating ratio of the template 10 is low, so that defects can be further reduced.

Before the first resist material 160 is applied, the second resist material 170 is irradiated with light having a wavelength in range of wavelengths at which the second resist material 170 is photosensitive. As a result, since the volatilization of the second resist material 170 can be inhibited, the deterioration or the like of the second resist material 170 can be inhibited.

### Modification Example

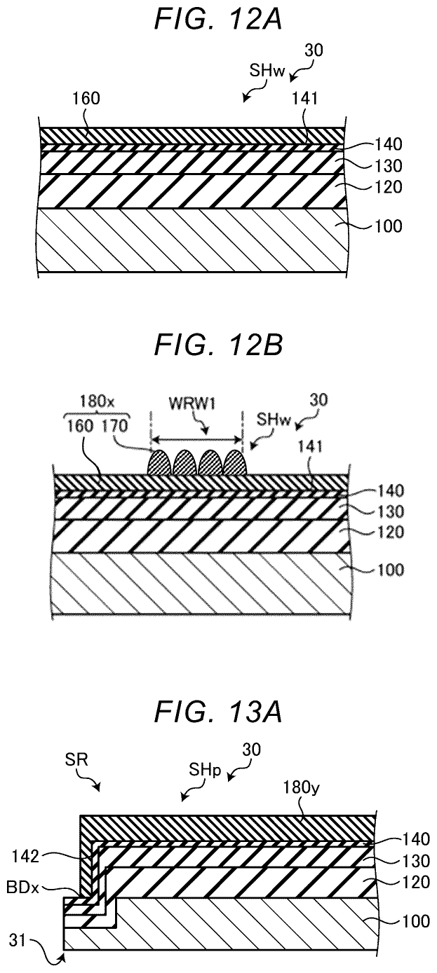

A modification example of the embodiment 2 will be described in detail with reference to FIGS. 12A and 12B. In the imprint method and the method for manufacturing a semiconductor device of the modification example, the time at which the coating of the first resist material 160 is performed before the deposition of the droplets of the second resist material 170, is different from that of the above-described embodiment 2. In addition, in the description below, the same reference numeral is attached to the same configuration as that in the above-described embodiment 2, and the description thereof may be omitted.

FIGS. 12A and 12B are views showing a process performed on the wafer 30 in the process of manufacturing the semiconductor device according to the modification example of the embodiment 2. FIGS. 12A and 12B show a cross-sectional view of the wafer in the predetermined normal shot SHw. In the modification example as well, the processing of FIGS. 3A and 3B and the processing of FIG. 6A and subsequent drawings in the embodiment 1 are performed.

First, as shown in FIG. 12A, the first resist material 160 is applied to the wafer 30 using a resist-applying device (not shown).

Next, as shown in FIG. 12B, the control unit 90 controls the droplet fall device 87 to deposit the droplet of the second resist material 170 on top of the first resist material 160 in the region WRW1 on the flat surface portion 141. At this time, the control unit 90 determines the region WRW1 based on the coating ratio map M.

After that, the process after FIG. 6A of the above-described embodiment is performed.

### Operation and Effect

According to the method for manufacturing the semiconductor device of the modification example, the same effects as those of the method for manufacturing the semiconductor device of the embodiment 2 described above are exhibited.

### Other Modification Examples

In embodiment 1 described above, a deposition position of the second resist material 170 is determined based on a result, where the wafer 30 on which the first resist material 160 is applied, is inspected by the inspection device 11, but the present disclosure is not limited thereto. For example, the deposition position of the second resist material 170 may be determined by monitoring the shearing force for each shot when the template 10 is pressed against the wafer 30. That is, for example, in the shot having the shearing force equal to or higher than a predetermined value, it is determined that the resist layer 180 is not formed between the template 10 and the wafer 30. Then, in the wafer 30 to be processed later, the shot may be determined as the deposition position of the second resist material 170.

In the above-described embodiment and the modification example, the wafer 20 and the wafer 30 include the bevel region 22, but the present disclosure is not limited thereto. For example, as the wafer 20 and the wafer 30, a flat substrate without a step may be used.

In the above-described embodiment and the modification example, it is assumed that the first resist material 160 and the second resist material 170 have the same composition, but the present disclosure is not limited thereto. For example, the first resist material 160 and the second resist material 170 may have different compositions.

The above-described embodiment and modification example may be combined in any manner.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. An imprint method comprising:
forming a liquid film of a first photocurable resin to have a substantially flat upper surface on a central region of a substrate;
depositing droplets of a second photocurable resin on an outer peripheral region of the substrate;
pressing a template against the first photocurable resin and the second photocurable resin;
irradiating the first photocurable resin and the second photocurable resin with light to cure the first photocurable resin and the second photocurable resin; and
releasing the template from the first photocurable resin and the second photocurable resin to expose a pattern on the substrate, that is formed by the cured first photocurable resin and the cured second photocurable resin.

2. The imprint method according to claim 1, wherein
the liquid film of the first photocurable resin is formed by a spin coating method, and
the droplets of the second photocurable resin are deposited by an inkjet method.

3. The imprint method according to claim 1, wherein
the droplets of the second photocurable resin are deposited after the liquid film of the first photocurable resin is formed.

4. The imprint method according to claim 3, further comprising:
acquiring location information of a peripheral edge portion of the first photocurable resin, wherein
the droplets of the second photocurable resin are deposited based on the location information.

5. The imprint method according to claim 1, wherein
the liquid film of the first photocurable resin is formed after the droplets of the second photocurable resin are deposited.

6. The imprint method according to claim 5, wherein
the second photocurable resin is irradiated with light having a wavelength in a range of wavelengths at which the second photocurable resin is photosensitive, before the liquid film of the first photocurable resin is formed.

7. The imprint method according to claim 1, wherein
the first photocurable resin and the second photocurable resin are irradiated with light having a wavelength in a range of wavelengths at which the first photocurable resin and the second photocurable resin are photosensitive.

8. The imprint method according to claim 7, wherein the first photocurable resin and the second photocurable resin are made of the same material.

9. An imprint method comprising:
determining a deposition position for droplets of a first photocurable resin on a substrate based on a coating ratio of a pattern of a template that is to be transferred to the substrate and depositing the droplets of the first photocurable resin on the substrate at the determined deposition position;
forming a second photocurable resin on the substrate on which the droplets of the first photocurable resin have been deposited;
pressing the template against the first photocurable resin and the second photocurable resin;
irradiating the first photocurable resin and the second photocurable resin with light to cure the first photocurable resin and the second photocurable resin; and
releasing the template from the first photocurable resin and the second photocurable resin to expose the pattern on the substrate, that is formed by the cured first photocurable resin and the cured second photocurable resin.

10. The imprint method according to claim 9, wherein
the second photocurable resin is formed after the droplets of the first photocurable resin are deposited.

11. The imprint method according to claim 10, wherein
the first photocurable resin is irradiated with light having a wavelength in a range of wavelengths at which the first photocurable resin is photosensitive before the second photocurable resin is formed.

12. The imprint method according to claim 10, wherein
the droplets of the first photocurable resin are deposited after the second photocurable resin is formed.

13. The imprint method according to claim 9, wherein
the droplets of the first photocurable resin are deposited at a position of the substrate corresponding to a location at which the coating ratio is equal to or less than a predetermined threshold value.

14. The imprint method according to claim 9, wherein
the first photocurable resin and the second photocurable resin are irradiated with light having a wavelength in a range of wavelengths at which the first photocurable resin and the second photocurable resin are photosensitive.

15. A method for manufacturing a semiconductor device, the method comprising:
preparing a substrate having a film to be processed formed thereon;
performing an imprint method on the substrate according to claim 9 to form a pattern on the substrate;
processing the film to be processed using the pattern as a mask; and
manufacturing a semiconductor device using the processed film to be processed.

16. A method for manufacturing a semiconductor device, the method comprising:
forming a film to be processed on a substrate;
forming a liquid film of a first photocurable resin to have a substantially flat upper surface on a central region of the substrate;
depositing droplets of a second photocurable resin on an outer peripheral region of the substrate;
pressing a template against the first photocurable resin and the second photocurable resin;
irradiating the first photocurable resin and the second photocurable resin with light to cure the first photocurable resin and the second photocurable resin;
releasing the template from the first photocurable resin and the second photocurable resin to expose a pattern on the film to be processed, that is formed by the cured first photocurable resin and the cured second photocurable resin;
processing the film to be processed using the pattern as a mask; and
manufacturing a semiconductor device using the processed film to be processed.

17. The method for manufacturing a semiconductor device according to claim 16, wherein
the liquid film of the first photocurable resin is formed by a spin coating method, and
the droplets of the second photocurable resin are deposited by an inkjet method.

18. The method for manufacturing a semiconductor device according to claim 16, wherein
the droplets of the second photocurable resin are deposited after the liquid film of the first photocurable resin is formed.

19. The method for manufacturing a semiconductor device according to claim 16, wherein
the droplets of the second photocurable resin are deposited after the liquid film of the first photocurable resin is formed.

20. The method for manufacturing a semiconductor device according to claim 19, further comprising:
acquiring location information of a peripheral edge portion of the first photocurable resin, wherein
the droplets of the second photocurable resin are deposited based on the location information.
